(19) United States
(12) Patent Application Publication
(10) Pub. No.: US 2017/0033061 A1
(43) Pub. Date: Feb. 2, 2017

(54) MITIGATING TRANSIENT TSV-INDUCED IC SUBSTRATE NOISE AND RESULTING DEVICES

(71) Applicant: GLOBALFOUNDRIES Inc., Grand Cayman (KY)

(72) Inventors: Mohamed RABIE, Clifton Park, NY (US); Premachandran CHIRAYARIKATHUVEEDU, Clifton Park, NY (US)

(21) Appl. No.: 14/812,340

(22) Filed: Jul. 29, 2015

(51) Int. Cl. H01L 23/64; H01L 23/528; H01L 21/768; H01L 21/3205; H01L 23/58; H01L 23/48

(52) U.S. Cl. CPC H01L 23/64; H01L 23/585; H01L 23/481; H01L 21/76877; H01L 21/32055; H01L 23/528

(57) ABSTRACT

Methods for creating effective noise reducing structures in an IC device to significantly reduce TSV-induced noise in an IC substrate of the IC device and the resulting device are disclosed. Embodiments include providing a plurality of circuits on an upper surface of an IC substrate; providing an active TSV in proximity to the circuits, wherein the TSV extends through the IC substrate; forming a noise reducing structure connected to a perimeter of a vertical segment of the active TSV; and connecting the noise reducing structure to an electrical ground node in common with the circuits.

### TECHNICAL FIELD

The present disclosure relates generally to designing and fabricating integrated circuit (IC) devices. The present disclosure is particularly applicable to mitigating transient signals/noise that may be induced by through-silicon vias (TSVs) in IC devices.

### BACKGROUND

Generally, a plurality of devices/components (e.g., transistors, diodes, etc.) may be designed and embedded into an IC chip/die, which then may be placed into a package (e.g., plastic casing) or used as a bare die for placement onto a printed circuit board (PCB) of an electronic device. Due to limited space availability on the PCBs, some manufacturers of the IC chips are integrating multiple IC chips into 2.5-dimensional (2.5D) or 3D IC chip stacks that would offer a smaller footprint on a PCB. An IC chip stack may include several logic, memory, analog, or other chips, which may be connected to each other by using a TSV architecture. Typically, TSVs are vertical vias etched into a silicon layer and filled with a conducting material (e.g., copper (Cu)), to provide connectivity for transfer of electronic signals or power supply between the vertically stacked IC chips. In addition to traditional technology node scaling at the transistor level, 2.5D/3D IC chip stacking is increasingly being utilized to provide solutions for meeting performance, power, and bandwidth requirements of various electronic devices.

FIG. 1 schematically illustrates an example IC chip stack structure including a plurality of TSVs. As illustrated, the 3D IC chip stack includes IC chips 101, 103, and 105 with TSVs 107 used to interconnect two adjacent chips (e.g., 101 and 103 or 103 and 105) at interconnection layers 109. Interconnection layer 109 may, for example, include micro-bumps to form a vertical stack of IC chips (e.g., 101 and 103 or 103 and 105), which then may be connected to a package substrate 111 through another interconnection layer 113 (e.g., including a C4 ball grid array). As illustrated, the IC chips may include a front metal layer 115, a back metal layer 117, a device layer 119, and a silicon layer/IC substrate 121.

An active TSV may provide connectivity for transferring electrical signals or power intra and inter chips in a chip stack as well as from a chip stack to a package substrate. TSVs are metal-oxide-silicon (MOS) structures that can produce strong electrical couplings with silicon or other semiconductor material in an IC substrate, and exhibit capacitance-voltage characteristics similar to a planar MOS capacitor. However, changes in a signal (e.g., transition from 0 to 1 or from 1 to 0 in a digital square pulse) being transferred through a TSV can induce undesirable transient signal/noise (e.g., electrical current), which may adversely impact components implemented in the IC substrate. For example, signals travelling through a TSV may cause a transient increase or decrease in a threshold of “on” or “off” state in a transistor/circuit near the TSV, and as a result, the transistor/circuit may unintentionally turn “on or off” or its current leakage may increase. In the case of an analog circuit, transient signals may change a biasing point of the circuit and affect its operation. A transient increase in a leakage current of a disconnected circuit near a TSV may cause undesirable power leakage, which can be as much as 70 times higher than an acceptable (e.g., maximum) value for the leakage and can cause a latch up between different (e.g., p-type and n-type) components in an IC device.

FIGS. 2A through 2F illustrate example layout diagrams of IC chips including TSVs. FIG. 2A illustrates a top view of a device layer 119 in an IC chip (e.g., 101) in which an active TSV 107 extends through the device layer 119 that includes circuits 201 (e.g., including transistors, diodes, capacitors, inductors, etc.) As noted earlier, a signal being transferred through an active TSV may induce undesirable transient signals (e.g., noise) in the IC substrate 121 (not shown for illustrative convenience) and a well area 203. Adverting to FIG. 2B now, an active TSV, e.g., TSV 107, can be moved away from the circuits 201 and the well area 203 into a keep-out-zone (KOZ), for example, by a distance of 205 and 207, respectively. The KOZ may range, for example, from 2 to 15 μm from the circuits 201 and well area 203. However, a reasonable KOZ cannot sufficiently mitigate the noise in the IC substrate/well. Additionally, the KOZ would waste precious layout area in the device layer as no devices would be implemented in that area.

As illustrated in FIG. 2C, in addition to a KOZ (e.g., at 205 and 207), a guard-ring 209 may be implemented at the device layer 119, around the perimeter of the active TSV 107. The guard-ring may be a heavily doped and grounded layer, in which heavily doped is defined as impurities added to the IC substrate in concentrations greater than 1×10¹⁹ cm⁻³, for better electrical conductivity. However, even with a guard-ring 209 added to a large (e.g., 15 μm) KOZ, the IC substrate noise (e.g., current) can still remain, for example, three times higher than an acceptable noise or leakage current level (e.g., target/maximum) for an affected circuit, resulting in malfunctions. The guard-ring 209 may filter the noise/current that is relatively close to the upper surface of the device layer 119, but deeper current paths in the IC substrate can bypass the guard-ring. Further, silicon space is still wasted due to the KOZ.

FIG. 2D illustrates another approach to address the noise in the device layer 119 by adding a shield-grounded TSV 211 in the KOZ area (e.g., between the well 203 and the guard-ring 209.) The additional shield-grounded TSV may reduce IC substrate leakage by about 13% more. Still, this approach may not sufficiently mitigate the noise in the IC substrate and device layer, as the capacitive nature of the shield-grounded TSV is not an efficient block to the noise/current. Further, silicon space continues to be wasted.

In FIGS. 2E and 2F, grounded metal plugs 213 may be implemented in the IC substrate 121 to reduce propagation of the noise due to an active TSV 107. FIG. 2E illustrates an example where the grounded metal plugs 213 are implemented around the active TSV 107 from a lower surface 215 of the IC substrate 121 and extend into the IC substrate 121. In FIG. 2F, the grounded metal plugs 213 are implemented around the active TSV 107 from the upper surface of the device layer 119 and extend into the IC substrate 121. However, the metal plugs 213 may contaminate the IC substrate material (e.g., silicon) as the metal plugs 213 would have to be embedded deep into the IC substrate; also implementation of the metal plugs 213 would require additional fabrication processing steps.

A need therefore exists for a methodology enabling creation of effective noise reducing structures in an IC device to significantly reduce TSV-induced noise in an IC substrate of the IC device and the resulting device.

### SUMMARY

An aspect of the present disclosure is a method of using a polysilicon buffer around TSVs to significantly reduce TSV-induced noise in an IC substrate of the IC device.

Another aspect of the present disclosure is a polysilicon buffer around TSVs in an IC device to significantly reduce TSV-induced noise in an IC substrate of the IC device.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure some technical effects may be achieved in part by a method including providing a plurality of circuits on an upper surface of an IC substrate; providing an active TSV in proximity to the circuits, wherein the TSV extends through the IC substrate; forming a noise reducing structure connected to a perimeter of a vertical segment of the active TSV; and connecting the noise reducing structure to an electrical ground node in common with at least one of the circuits.

Another aspect of the method includes forming the noise reducing structure from an upper surface of the IC substrate and extending into the IC substrate along the vertical segment of the active TSV. An additional aspect of the method includes connecting the noise reducing structure to a dielectric liner on the perimeter of the active TSV.

One aspect of the method includes forming a noise guard-ring layer, on the upper surface of the IC substrate, spaced from and surrounding a perimeter of the noise reducing structure; and connecting the noise guard-ring layer to the electrical ground node.

A further aspect of the method includes forming the noise reducing structure and the noise guard-ring layer based, at least in part, on characteristics of an electrical signal transferred through the active TSV. One aspect of the method includes forming the noise reducing structure and the noise guard-ring layer based, at least in part, on a lateral proximity of the active TSV to at least one of the circuits.

Some aspects of the method include forming the noise reducing structure and the noise guard-ring layer based, at least in part, on electrical characteristics of at least one of the circuits. In one aspect of the method, the noise reducing structure and the noise guard-ring layer channel away, from at least one of the circuits, transient signals caused by the electrical signal transferred through the active TSV. Another aspect of the method includes forming the noise reducing structure and the noise guard-ring layer from a heavily doped polysilicon material. One aspect of the method includes forming upper surfaces of the noise reducing structure and the noise guard-ring layer at a same level as the upper surface of the IC substrate, wherein a vertical center-axis of the active TSV is substantially aligned with a vertical center-axis of the noise reducing structure.

Another aspect of the present disclosure includes a semiconductor device including: a plurality of circuits on an upper surface of an IC substrate; an active TSV in proximity to the circuits, wherein the TSV extends through the IC substrate; a noise reducing structure connected to a perimeter of a vertical segment of the active TSV; and the noise reducing structure being connected to an electrical ground node in common with at least one of the circuits.

In one aspect of the semiconductor device, the noise reducing structure extends from an upper surface of the IC substrate into the IC substrate along the vertical segment of the active TSV. In some aspects of the semiconductor device, the noise reducing structure is connected to a dielectric liner on the perimeter of the active TSV.

A further aspect of the semiconductor device includes a noise guard-ring layer, on the upper surface of the IC substrate, spaced from and surrounding a perimeter of the noise reducing structure, wherein the noise guard-ring layer is connected to the electrical ground node.

In another aspect of the semiconductor device, the noise reducing structure and the noise guard-ring layer include characteristics based, at least in part, on characteristics of an electrical signal transferred through the active TSV. In a further aspect of the semiconductor device, the noise reducing structure and the noise guard-ring layer include characteristics based, at least in part, on a lateral proximity of the active TSV to at least one of the circuits.

In another aspect of the semiconductor device, the noise reducing structure and the noise guard-ring layer include characteristics based, at least in part, on electrical characteristics of at least one of the circuits. In some aspects of the semiconductor device, the noise reducing structure and the noise guard-ring layer channel away, from at least one of the circuits, transient signals caused by the electrical signal transferred through the active TSV. In yet another aspect of the semiconductor device, the noise reducing structure and the noise guard-ring layer are of a heavily doped polysilicon material. In a further aspect of the semiconductor device, upper surfaces of the noise reducing structure and the noise guard-ring layer are at a same level as the upper surface of the IC substrate, wherein a vertical center-axis of the active TSV is substantially aligned with a vertical center-axis of the noise reducing structure.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates an example of an IC chip structure including a plurality of TSVs;

FIGS. 2A through 2F schematically illustrate example IC chips including structures for reducing TSV-induced noise in the IC chips substrate;

FIG. 3A schematically illustrates an example IC chip including a noise reducing structure for mitigating TSV-induced noise in the IC chip substrate, in accordance with an exemplary embodiment;

FIG. 3B schematically illustrates an example IC chip including a noise reducing structure and a noise guard-ring for mitigating TSV-induced noise in the IC chip substrate, in accordance with an exemplary embodiment;

FIGS. 4A and 4B include timing diagrams illustrating data points associated with transient signals in an IC chip; and

FIG. 5 illustrates a table including data points associated with a polysilicon noise reducing structure.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the problem of TSV-induced noise in an IC substrate of an IC chip where the noise may adversely affect operation of devices/components/circuits in the IC chip. The present disclosure addresses and solves such problems, for instance, by, inter alia, creating a noise reducing structure in the IC substrate and connecting it to a perimeter of a vertical segment of an active TSV. Additionally, the noise reducing structure is connected to an electrical ground node in common with at least one of the circuits.

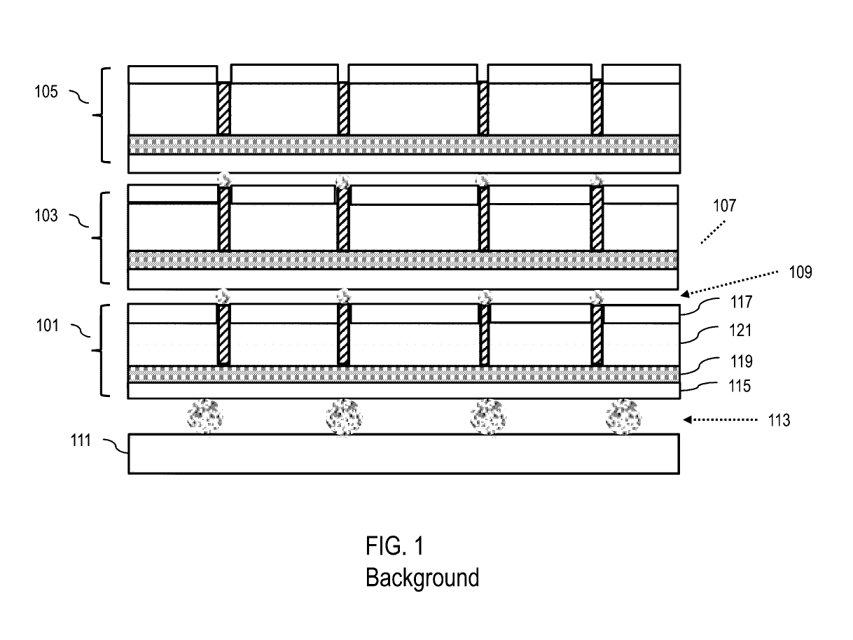

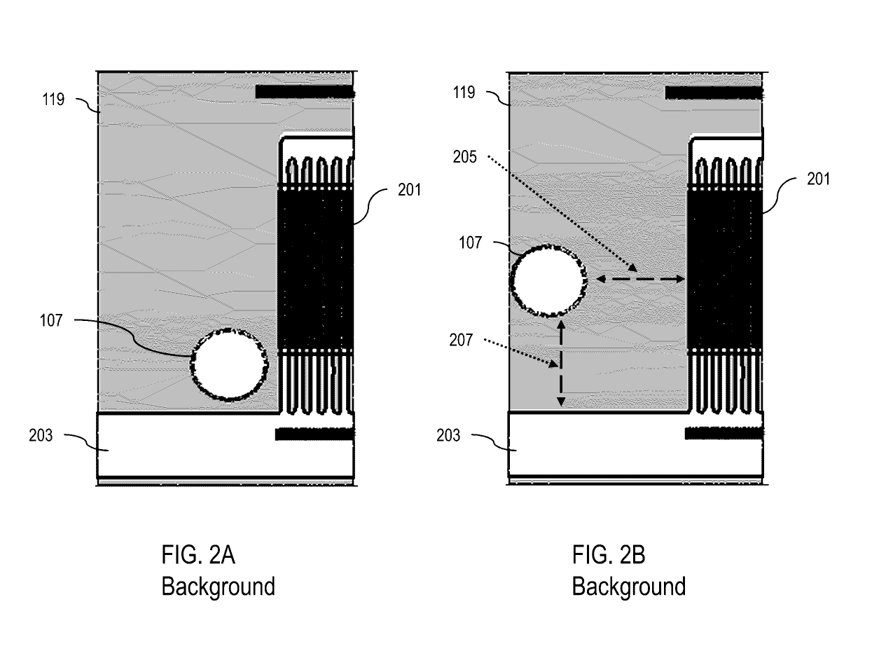

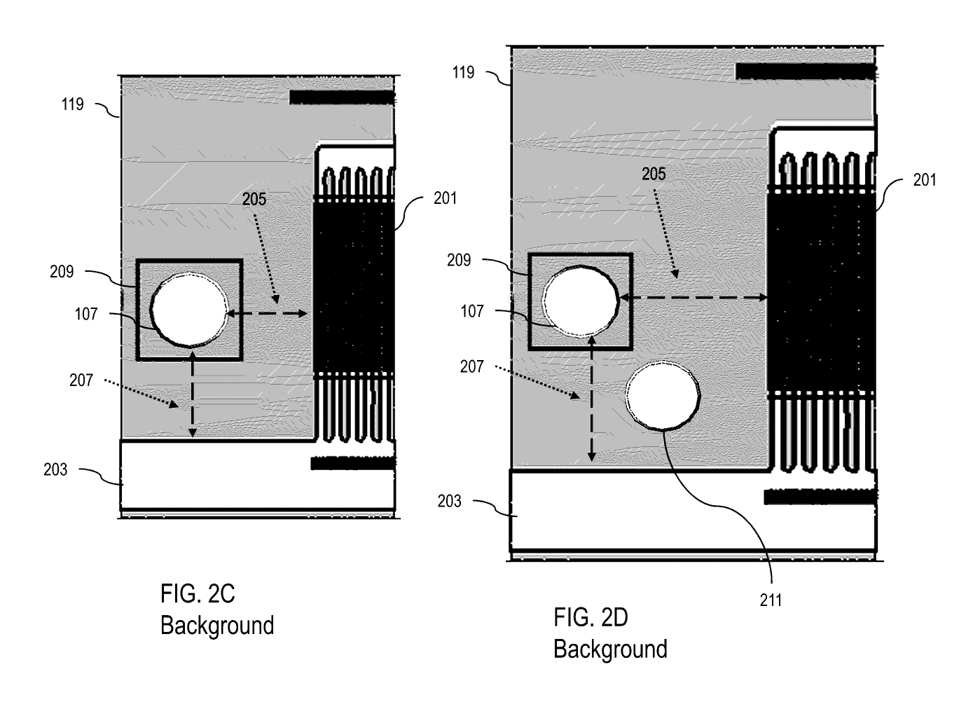

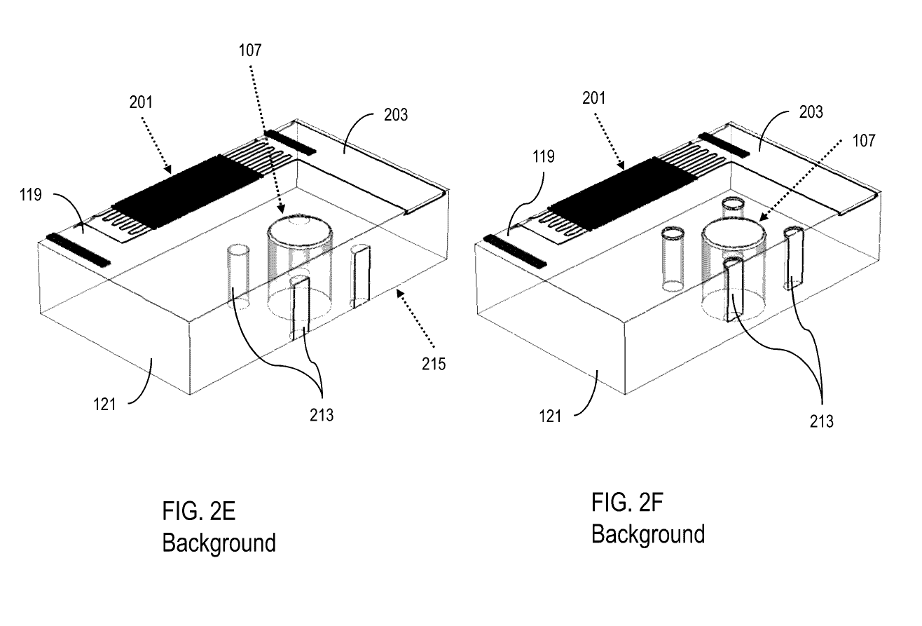

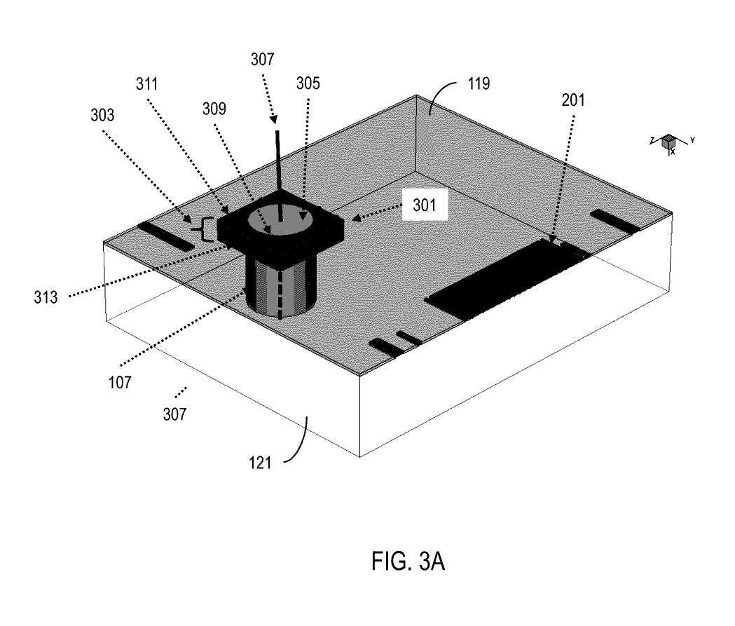

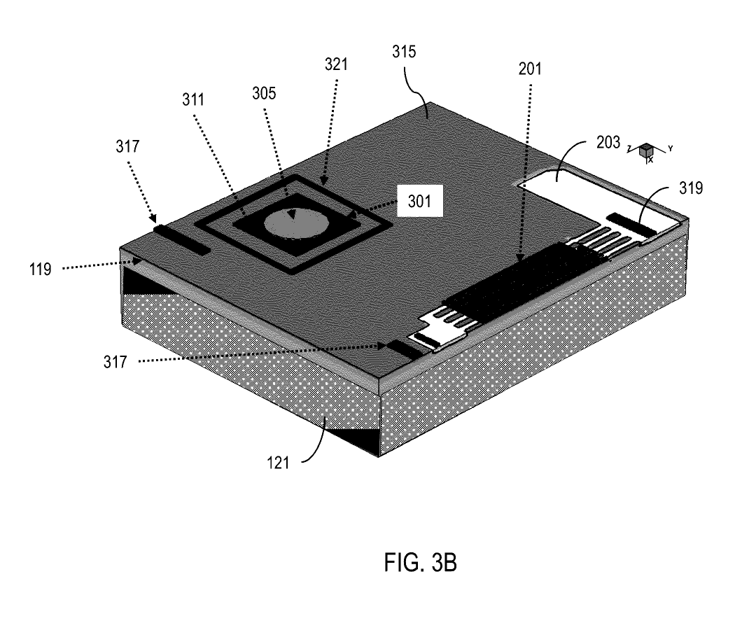

FIG. 3A illustrates a 3D view of an IC substrate 121 with circuits 201 implemented at a device layer 119. Also, an active TSV 107, near the circuits 201, extends from the upper surface of the device layer 119 through the IC substrate 121. The TSV 107 may provide connectivity for transferring electrical signals (e.g., communication, power, etc.), for example, from a chip (e.g., chip 101 in FIG. 1) above the package substrate 111, or chip 103 in FIG. 1, to another chip (e.g., chip 105 in FIG. 1), or chip 101 in FIG. 1. The IC substrate 121 also includes a noise reducing structure 301 connected to a perimeter of a vertical segment 303 of the active TSV 107. The noise reducing structure 301 is also connected to an electrical ground node in common with at least one of the IC circuits 201. The noise reducing structure 301 may channel away from at least one of the IC circuits 201 transient signals that may be induced by the active TSV 107, as electrical signals are transferred through it. For a better conductivity, the noise reducing structure 301 may be formed by using a heavily doped polysilicon material with a thickness of at least 1 μm. A heavily doped polysilicon may be defined as conductive polysilicon including impurities in concentrations greater than 1×10¹⁹ cm⁻³. The dopant may be, for example, Boron atoms for p-type, and Phosphorus or Arsenic for n-type devices.

Also, an upper surface 305 of the noise reducing structure 301 may substantially be at a same level as the upper surface of the IC substrate 121 and/or the device layer 119, with the vertical center-axes of the active TSV 107 and the noise reducing structure 301 substantially aligned to a same vertical center-axis 307. The noise reducing structure 301 may be connected to a dielectric liner 309 on the perimeter of the active TSV 107.

Characteristics of a noise reducing structure 301 may be based on various characteristics associated with an active TSV 107 and/or criteria associated with functionalities of one or more IC chips (e.g., 101, 103, and 105 of FIG. 1) interconnected by the active TSV 107. A thickness/depth 303 (which may range from 1 μm to 50 μm (TSV Depth)), dimensions of a surface area 311 (which may range from TSV diameter+0.1 μm to TSV diameter+few (3) μm, wherein shape of the noise reducing structure 301/surface area 311 may be square or conformal to a circular TSV such as 107), a doping level (which may range from 1×10¹⁵ cm⁻³ to 1×10²² cm⁻³) and/or dopant 313, etc., of the noise reducing structure 301 may be based on electrical signals transferred through the active TSV 107, a lateral proximity of the active TSV 107 to at least one of the IC circuits 201 or a well area 203 (not shown for illustrative convenience), and/or electrical characteristics or types of the circuits 201. For example, an active TSV 107 that is positioned very close to the circuits 201 may have a thicker noise reducing structure 301 (e.g., 4 μm to TSV Depth) to cover a longer vertical segment 303 of the active TSV 107. In another example, a noise reducing structure 301 may have a higher concentration level of a dopant (e.g., for better conductivity) so as to channel away higher density transient currents from more sensitive circuits 201.

FIG. 3B illustrates another 3D view of an IC substrate 121 including an oxide layer 315 formed to a thickness of 0.05 μm to 2 μm on the upper surface of the device layer 119. As noted earlier, the noise reducing structure 301 may be connected to an electrical ground node in common with at least one of the circuits 201; for example, at p-well contacts 317 while an n-well contact 319 may be connected to a positive voltage node (e.g., Vdd). Additionally, a noise guard-ring layer 321 may be formed in and on the upper surface of the oxide layer 315 where the noise guard-ring layer 321 may be spaced from and surrounding a perimeter of the noise reducing structure 301, wherein the noise guard-ring layer 321 may be connected to an electrical ground node in common with at least one of the circuits 201. Similar to the noise reducing structure 301, the noise guard-ring layer 321 may be formed from a heavily doped IC substrate material, which may further block and reduce some or all of the noise (e.g., current leakage) that may bypass the noise reducing structure 301.

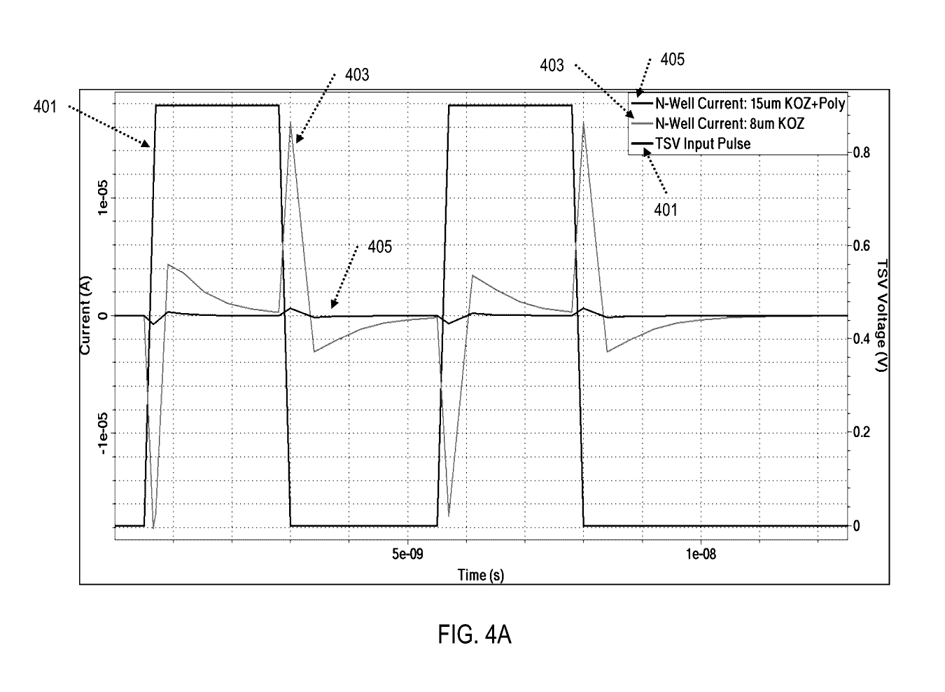

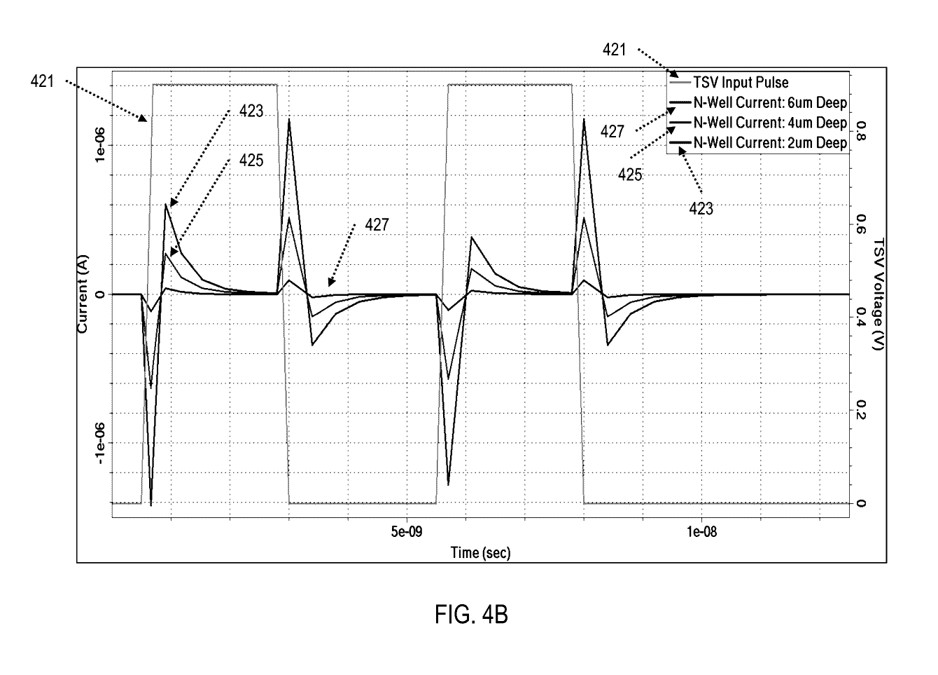

FIGS. 4A and 4B include timing diagrams illustrating data points associated with transient signals in an IC chip. FIG. 4A includes a timing diagram that illustrates a diagram of a signal 401 (e.g., TSV input) in an active TSV, which may induce transient signals in an n-well area of an IC substrate. A TSV positioned at a KOZ of 8 μm from a circuit/device for example may induce a transient signal 403. However, if the TSV is positioned at a KOZ of 15 μm from the circuit/device and a noise reducing structure is added to the TSV as well, then a TSV-induced transient signal may be reduced to a signal 405.

In FIG. 4B, another timing diagram illustrates a diagram of a TSV input signal 421 in an active TSV, which may induce transient signals in an n-well area of an IC substrate. A TSV positioned at a KOZ of 5 μm from a circuit/device may cause TSV-induced transient signals in an IC substrate; however, a noise reducing structure may be added to the TSV to mitigate the transient signals. For example, a noise reducing structure with a depth of 2 μm may reduce a transient signal to a signal 423. In another example, a noise reducing structure with a depth of 4 μm may further reduce the transient signal to a signal 425. In a further example, a noise reducing structure with a depth of 6 μm may reduce the transient signal to a signal 427.

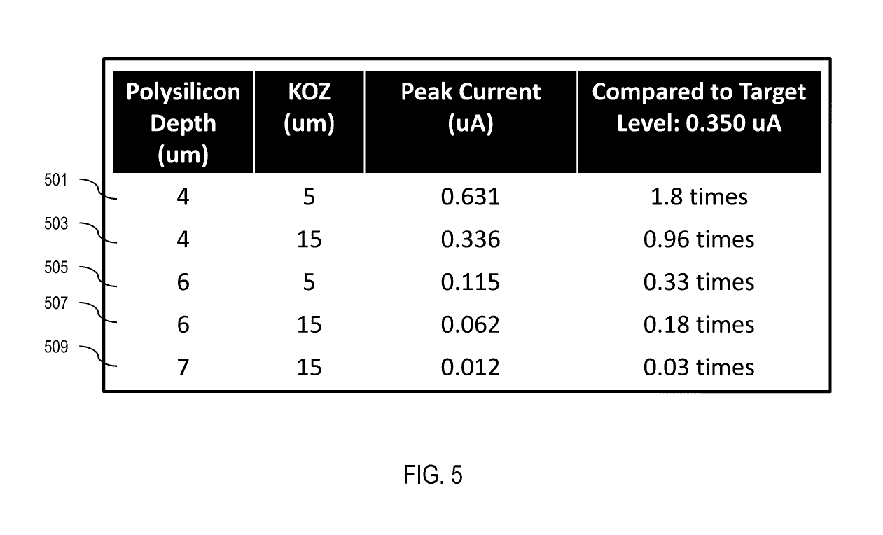

FIG. 5 illustrates a table including data points associated with a polysilicon noise reducing structure. Polysilicon noise reducing structures at different depths/thicknesses and KOZs can provide different levels of noise reduction in TSV-induced transient currents in an IC substrate. The data points are associated with an example ring-oscillator (RO) circuit that has a target level of 350 nano-Ampere (nA) for its leakage current, wherein a target level may be a minimum, optimal, maximum, or the like noise/leakage-current level for a given circuit. As illustrated, at 501, a polysilicon noise reducing structure with a thickness of 4 μm for an active TSV that is positioned at a KOZ of 5 μm (e.g., away from the RO circuit) may block and reduce a transient current to 0.631 μA, which is still 1.8 times (e.g., 180%) the target level of 350 nA (0.350 μA). At 503, a polysilicon noise reducing structure with a thickness of 4 μm for an active TSV that is positioned at a KOZ of 15 μm may block and reduce a transient current to 0.336 μA, which is at 96% of the target level of 350 nA.

At 505, a polysilicon noise reducing structure with a thickness of 6 μm for an active TSV that is positioned at a KOZ of 5 μm may block and reduce a transient current to 0.115 μA, which is at 33% of the target level of 350 nA. At 507, a polysilicon noise reducing structure with a thickness of 6 μm for an active TSV that is positioned at a KOZ of 15 μm may block and reduce a transient current to 0.062 μA, which is at 18% of the target level of 350 nA. At 509, a polysilicon noise reducing structure with a thickness of 7 μm for an active TSV that is positioned at a KOZ of 15 μm may block and reduce a transient current to 0.012 μA, which is at 3% of the target level of 350 nA.

The embodiments of the present disclosure can achieve several technical effects including creating effective noise reducing structures in an IC device to significantly (e.g., 98%) reduce TSV-induced noise in an IC substrate of the IC device. The proposed noise reducing structures may be implemented by use of current fabrication processes to save silicon space and without causing metal contamination in the silicon. Furthermore, the embodiments enjoy utility in various industrial applications as, for example, microprocessors, smart phones, mobile phones, cellular handsets, set-top boxes, DVD recorders and players, automotive navigation, printers and peripherals, networking and telecom equipment, gaming systems, digital cameras, or other devices utilizing logic or high-voltage technology nodes. The present disclosure therefore enjoys industrial applicability in any of various types of highly integrated semiconductor devices, including devices that use static-random-access memory (SRAM) cells (e.g., liquid crystal display (LCD) drivers, digital processors, etc.)

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A method comprising:
providing a plurality of circuits on an upper surface of an integrated circuit (IC) substrate;
providing an active through-silicon via (TSV) in proximity to the circuits, wherein the TSV extends through the IC substrate and has a vertical segment adjacent to the upper surface of the IC substrate;
forming a noise reducing structure connected to a perimeter of the vertical segment of the active TSV, wherein the noise reducing structure surrounds and contacts the vertical segment of the TSV; and
connecting the noise reducing structure to an electrical ground node in common with the circuits.

2. The method according to claim 1, further comprising:
forming the noise reducing structure from the upper surface of the IC substrate and extending into the IC substrate along the vertical segment of the active TSV; and
connecting the noise reducing structure to a dielectric liner on the perimeter of the active TSV.

3. The method according to claim 1, further comprising:
forming a noise guard-ring layer, on the upper surface of the IC substrate, spaced from and surrounding a perimeter of the noise reducing structure; and
connecting the noise guard-ring layer to the electrical ground node.

4. The method according to claim 3, further comprising:
forming the noise reducing structure and the noise guard-ring layer based on characteristics of an electrical signal transferred through the active TSV.

5. The method according to claim 4, further comprising:
forming the noise reducing structure and the noise guard-ring layer based on a lateral proximity of the active TSV to the circuits.

6. The method according to claim 5, further comprising:
forming the noise reducing structure and the noise guard-ring layer based on electrical characteristics of the circuits.

7. The method according to claim 3, wherein the noise reducing structure and the noise guard-ring layer channel away, from the circuits, transient signals caused by the electrical signal transferred through the active TSV.

8. The method according to claim 3, further comprising:
forming the noise reducing structure and the noise guard-ring layer from a heavily doped polysilicon material.

9. The method according to claim 1, further comprising:
forming upper surfaces of the noise reducing structure and the noise guard-ring layer at a same level as the upper surface of the IC substrate, wherein a vertical center-axis of the active TSV is substantially aligned with a vertical center-axis of the noise reducing structure.

10. A semiconductor device comprising:
a plurality of circuits on an upper surface of an integrated circuit (IC) substrate;
an active through-silicon via (TSV) in proximity to the circuits, wherein the TSV extends through the IC substrate;
a noise reducing structure connected to a perimeter of a vertical segment of the active TSV; and
the noise reducing structure being connected to an electrical ground node in common with the circuits.

11. The semiconductor device according to claim 10, further comprising:
the noise reducing structure extending from an upper surface of the IC substrate into the IC substrate along the vertical segment of the active TSV, wherein the noise reducing structure is connected to a dielectric liner on the perimeter of the active TSV.

12. The semiconductor device according to claim 10, further comprising:
a noise guard-ring layer, on the upper surface of the IC substrate, spaced from and surrounding a perimeter of the noise reducing structure, wherein the noise guard-ring layer is connected to the electrical ground node.

13. The semiconductor device according to claim 12, further comprising:
the noise reducing structure and the noise guard-ring layer include characteristics based, at least in part, on characteristics of an electrical signal transferred through the active TSV.

14. The semiconductor device according to claim 13, further comprising:
the noise reducing structure and the noise guard-ring layer include characteristics based, at least in part, on a lateral proximity of the active TSV to the circuits.

15. The semiconductor device according to claim 14, further comprising:
the noise reducing structure and the noise guard-ring layer include characteristics based, at least in part, on electrical characteristics of the circuits.

16. The semiconductor device according to claim 12, wherein the noise reducing structure and the noise guard-ring layer channel away, from the circuits, transient signals caused by the electrical signal transferred through the active TSV.

17. The semiconductor device according to claim 12, further comprising:
the noise reducing structure and the noise guard-ring layer of a heavily doped polysilicon material.

18. The semiconductor device to claim 12, wherein upper surfaces of the noise reducing structure and the noise guard-ring layer are at a same level as the upper surface of the IC substrate, and wherein a vertical center-axis of the active TSV is substantially aligned with a vertical center-axis of the noise reducing structure.

19. A method comprising:
providing a plurality of circuits on an upper surface of an integrated circuit (IC) substrate;
providing an active through-silicon via (TSV) in proximity to the circuits, wherein the TSV extends through the IC substrate and has a vertical segment adjacent to the upper surface of the IC substrate;
forming a noise reducing structure connected to a dielectric liner on a perimeter of the vertical segment of the active TSV, wherein the noise reducing structure extends from an upper surface of the IC substrate into the IC substrate along the vertical segment of the active TSV, wherein the noise reducing structure surrounds and contacts the vertical segment of the TSV;
forming a noise guard-ring layer, on the upper surface of the IC substrate, spaced from and surrounding a perimeter of the noise reducing structure; and
connecting the noise reducing structure and the noise guard-ring layer to an electrical ground node in common with the circuits, wherein the noise reducing structure and the noise guard-ring layer channel away, from the circuits, transient signals caused by the electrical signal transferred through the active TSV.

20. The method according to claim 19, further comprising:
forming the noise reducing structure and the noise guard-ring layer from a heavily doped polysilicon material;
forming upper surfaces of the noise reducing structure and the noise guard-ring layer at a same level as the upper surface of the IC substrate, wherein a vertical center-axis of the active TSV is substantially aligned with a vertical center-axis of the noise reducing structure; and
forming the noise reducing structure and the noise guard-ring layer based on characteristics of an electrical signal transferred through the active TSV, a lateral proximity of the active TSV to the circuits, electrical characteristics of the circuits, or a combination thereof.
